(19) United States
(12) Patent Application Publication
(10) Pub. No.: US 2007/0026653 A1
(43) Pub. Date: Feb. 1, 2007

(54) Cap layer on doped dielectric

(75) Inventors: Po-Hsiung Leu, Lujhu Township (TW); Shu-Tine Yang, Tuku Township (TW); Ying-Hsiu Tsai, Hsin-Chu (TW); Shin-Yeu Tsai, Liouying Township (TW); Tsang-Yu Liu, Hsin-Chu (TW); Ming-Te Chen, Hsin-Chu (TW); Szu-An Wu, Hsin-Chu (TW); Harry Chuang, Austin, TX (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/189,613

(22) Filed: Jul. 26, 2005

(51) Int. Cl. H01L 21/22

(52) U.S. Cl. 438/563; 257/E21.278

(57) ABSTRACT

A method for capping over a doped dielectric. The method comprises providing a substrate and depositing a doped dielectric layer on the substrate from a gas mixture. The gas mixture comprises a silicon source gas, a dopant gas and an oxygen source gas. A cap layer is in-situ deposited on the doped dielectric layer from the gas mixture substantially in absence of the dopant gas.

### BACKGROUND

The invention relates to a semiconductor process and in particular to a semiconductor device comprising a cap layer and methods for capping over a doped dielectric layer.

In order to fabricate semiconductor devices, it is necessary to employ layers of dielectric material to electrically insulate patterned conductive material layers which serve as interconnects of devices in the fabrication of microelectronics. As semiconductor devices have become more complex and densely populated the requirements on the conductive and dielectric layers have become more stringent. The need to minimize power requirements and resistive losses has led to the employment of materials with higher electrical conductivity such as copper, for example. These conductive layers are often fabricated in complex and sophisticated configurations such as inlaid or damascene designs in order to maintain surface planarity in multi-layer structures. The conductive layer may act as a diffusion barrier towards substances emanating from other layers or, conversely, the conductive layer may require a barrier layer to protect it from deleterious substances or to protect other layers from itself.

Dielectric materials which are useful for formation of dielectric layers employed within semiconductor fabrications often are desired to have low dielectric constants to increase circuit performance. Such low dielectric constant materials as organic polymer dielectric materials or doped silicon glass dielectric materials are commonly employed. The doped silicon glass dielectric materials comprise fluorine-doped silicon glass (FSG), boron-doped silicon glass (BSG) and phosphor-doped silicon glass (PSG). Likewise, increased circuit density and complexity has also led to multiple conductive layers and dielectric layers being fabricated into intermetal dielectric (IMD) layers to enable accommodation of all the requirements of increased circuit density and interconnect ability. Although methods and materials are available which are satisfactory for these purposes generally, the employment of low dielectric constant dielectric layers still has some problems.

For example, FSG has fluorine diffusion and precipitation problems. The fluorine diffusion problem may cause bubbles in the dielectric layer and induce film delamination. The fluorine precipitation may induce metal bridging in the dielectric layer and deterioration of device performance. Furthermore, fluorine is unstable in an open environment, thus a long queue time (Q time) is inappropriate. Traditionally, a Q time is shorter than 8 hours, is detrimental to production.

Therefore, a method is needed to prevent fluorine diffusion and precipitation and prolong the Q time.

### SUMMARY

A semiconductor device and methods for capping over a doped dielectric are provided. An embodiment of a method for capping over a doped dielectric comprises depositing a doped dielectric layer on a substrate from a gas mixture. The gas mixture comprises a silicon source gas, a dopant gas and an oxygen source gas. A cap layer is in-situ deposited on the doped dielectric layer from the gas mixture substantially in absence of the dopant gas.

Another embodiment of a method capping over a doped dielectric comprises providing a substrate in a chamber and injecting a gas mixture into the chamber. The gas mixture comprises a silicon source gas, fluorine source gas and an oxygen source gas. Plasma is generated to deposit a fluorine-doped silicon glass (FSG) layer on the substrate by applying a radio frequency (RF) power. A cap layer is in-situ deposited on the FSG layer by continuing applying the RF power and injecting the silicon source gas and the oxygen source gas into the chamber, while substantially stopping injection of the fluorine source gas. The fluorine content near the top surface of the cap layer is lower than that in the fluorine-doped silicon glass.

### DESCRIPTION OF THE DRAWINGS

The invention can be more fully understood by reading the subsequent detailed description and examples with references made to the accompanying drawings, wherein:

FIG. 1 is a cross section of an embodiment of a method for capping over a doped dielectric layer.

FIG. 2 is a conventional processing timing diagram for the formation of a doped dielectric layer.

FIG. 3 is a processing timing diagram for the formation a doped dielectric layer with a cap layer thereon shown in FIG. 1.

### DETAILED DESCRIPTION

The invention relates to an improved process for fabricating a semiconductor device, using an oxide rich cap layer for an intermetal or interlayer dielectric (IMD or ILD) layer to enhance insulating and adhesion properties while prolonging the Q time.

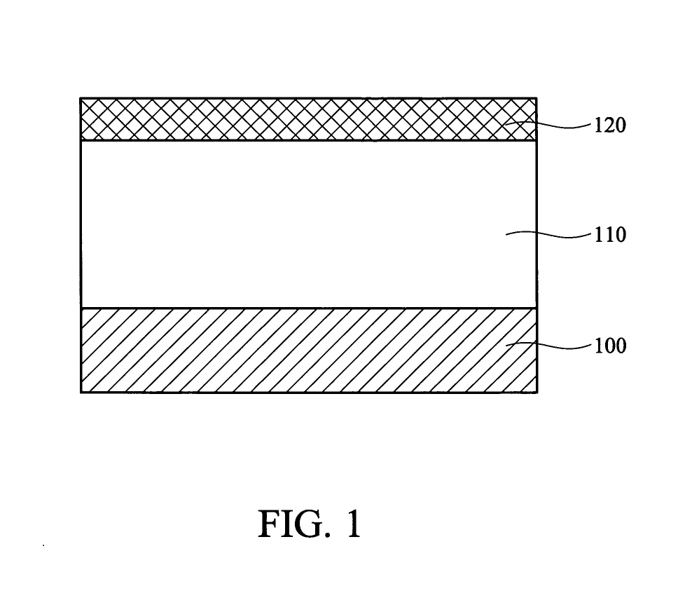

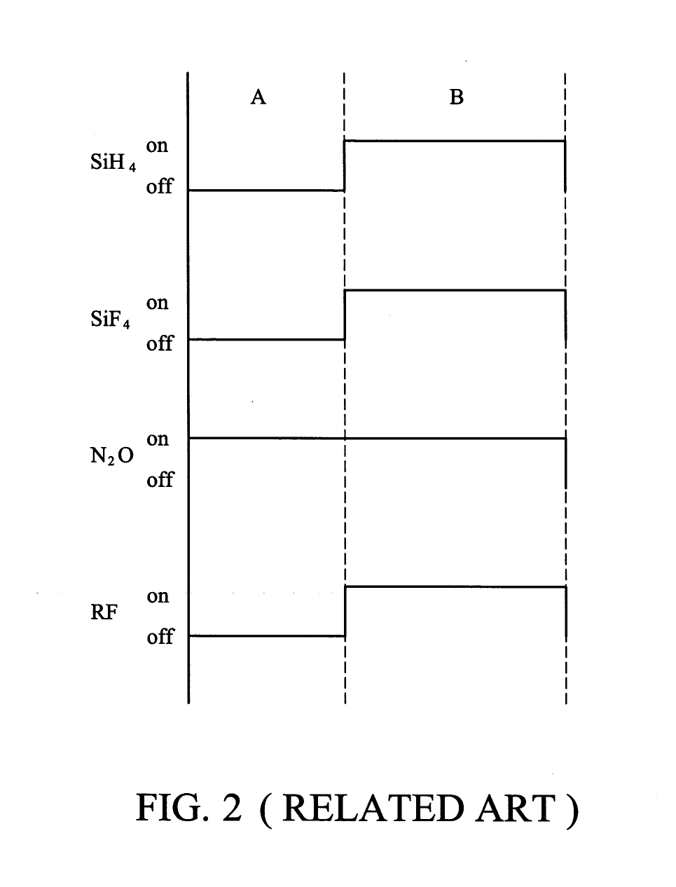

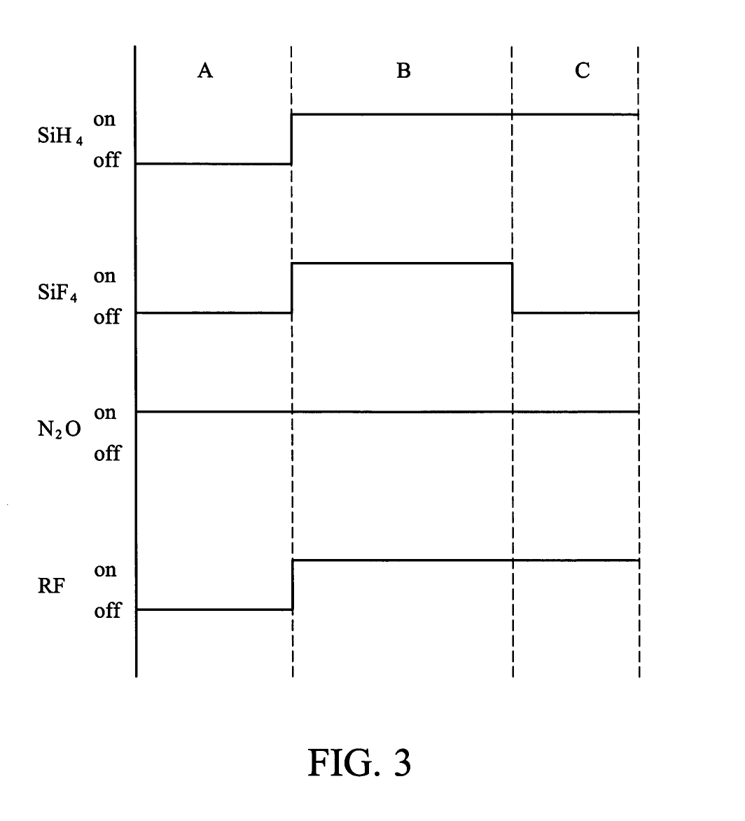

FIG. 1 illustrates a method for capping over a doped dielectric layer. FIG. 2 illustrates a conventional process timing diagram for the formation of a doped dielectric layer and FIG. 3 an improved process timing diagram for the formation of a doped dielectric layer 110 with a cap layer 120 thereon shown in FIG. 1. In FIG. 2, label A represents the preheated period and label B the fluorine-doped dielectric layer deposition period. Also, in FIG. 3, process periods the same as process periods in FIG. 2 bear the same labels. Moreover, an additional label C represents the oxygen rich cap layer deposition period. As shown in FIG. 1, a substrate 100, such as a silicon substrate or other semiconductor substrate, is provided. The substrate 100 may contain a variety of elements, including, for example, transistors, resistors, and other semiconductor elements as are well known in the art. The substrate 100 may also contain conductive layers. The conductive layer is typically a layer comprising metal, such as copper, commonly used in the semiconductor industry for wiring the discrete semiconductor devices in and on the substrate. In order to simplify the diagram, a flat substrate is depicted.

The substrate 100 is put into a process chamber (not shown), such as a plasma deposition chamber. Next, the substrate 100 is preheated in an ambient environment comprising oxygen. For example, an oxygen source gas, such as NO₂, may be injected into the chamber during preheating of the substrate 100, as in the process period A shown in FIGS. 2 and 3.

A doped dielectric layer 110 serving as an ILD or IMD layer, is deposited on the substrate 100. The doped dielectric layer may comprise a low k material comprising at least C or N. Moreover, the low k material may have a dielectric constant less than 3.5. In this embodiment, the doped dielectric layer 110 is formed by, for example, plasma enhanced chemical vapor deposition (PECVD) or High density plasma chemical vapor deposition (HDP CVD) from a gas mixture comprising a silicon source gas, a dopant gas and the oxygen source gas. For example, the silicon source gas may comprise SiH₄ or Tetra-Ethyl-Ortho-Silicate (TEOS). The oxygen source gas may comprise N₂O, O₂ or O₃. The dopant gas may comprise at least SiF₄, B₂H₆ or PH₃. Depending on the choice of the dopant gas, the doped dielectric layer 110 may be a fluorine-doped dielectric layer, boron-doped dielectric layer or a phosphorous-doped dielectric layer. That is, the fluorine-doped dielectric layer may be formed using a dopant gas comprising fluorine, such as SiF₄ or C₂F₆. The boron-doped dielectric layer may be formed using a dopant gas comprising boron, such as B₂H₆ or Tri-Ethyl-Borate (TEB). The phosphorous-doped dielectric layer formed using a dopant gas comprising phosphorous PH₃ or Tri-Methyl-Phosphate (TMPO). For simplification and clarification, we take fluorine-doped dielectric layer as an embodiment in the following description. Note that it is to be understood that the invention is not limited thereto and one skilled in the art should realize and understand that other doped dielectric layers can be formed and improved by the invention.

During the deposition of fluorine-doped dielectric layer 110, the silicon source gas, the oxygen source gas, and the fluorine source gas are injected into the chamber. Additionally, a radio frequency (RF) power is simultaneously turned on to generate plasma in the chamber for the formation of the fluorine-doped dielectric layer 110, as the process period B shown in FIGS, 2 and 3. In this embodiment, the applied RF power is about 500˜5000 Watts.

Conventionally, after the deposition of the fluorine-doped dielectric layer, injection of all the silicon, fluorine and oxygen source gases into the chamber substantially stops. At the same time, the RF power is turned off. In the chamber, however, the unreacted fluorine ions from the residual fluorine source gas may result in an unstable surface of the fluorine-doped dielectric layer, thus shortening the Q time. Moreover, the fluorine diffusion in the dielectric layer may cause bubbles, resulting in film delamination. Additionally, the fluorine precipitation may further induce metal bridging in subsequent metallization, deteriorating device performance.

In order to eliminate the problems as set forth, an in-situ cap layer 120 is further formed on the fluorine-doped dielectric layer 110, as shown in FIG. 1. The process period C shown in FIG. 3 is the formation period of the cap layer 120. The cap layer 120 is in-situ deposited on the fluorine-doped dielectric layer 110 from the gas mixture substantially in absence of the dopant gas, such as SiF₄ or C₂F₆.

That is, the cap layer 120 is deposited on the fluorine-doped dielectric layer 110 by continuing injection of the silicon and oxygen source gases into the chamber and simultaneously applying (turning on) the RF power, while substantially stopping injection of fluorine source gas. As a result, an oxygen rich cap layer 120 may be formed on the fluorine-doped dielectric layer 110. Moreover, the formed cap layer 120 may have a gradient dopant (I.e. fluorine) concentration therein. Here, the dopant content near the top surface of the cap layer 120 is substantially equal to zero and that near the bottom surface of the cap layer is substantially same as the fluorine-doped dielectric layer 110. That is, the fluorine content near the top surface of the cap layer 120 is lower than that in the fluorine-doped dielectric layer 110. In this embodiment, the RF power is about 500˜5000 Watts and is applied for less than 10 sec. The oxygen rich cap layer 120 has an oxygen to silicon ratio of about 1.8˜2.5, a refractive index of about 1.42˜1.46, and a thickness smaller than 500 Å.

Due to the cap layer with less dopant concentration, the dopant diffusion and precipitation problems can be eliminated. Moreover, the cap layer prevents the dopant in dielectric layer from exposure to the open environment, thus the Q time is longer than a conventional dielectric layer without an in-situ cap layer with less dopant concentration thereon. The Q time can be prolonged from less than 8 hours to about 48 hours. Furthermore, since the cap layer is in-situ formed in the same chamber with the doped dielectric layer, the throughput can be maintained.

In some embodiments, when the deposition of the doped dielectric layer is complete, the RF power must be turned off after substantially stopping injection of the silicon and dopant source gases into the chamber, thereby ensuring the dopant can be completely reacted with the plasma generated by RF power. For example, the RF power is turned off more than one second after the injection of the silicon and dopant source gases into the chamber has stopped. Accordingly, a doped dielectric layer with a stable surface can be obtained.

An etch stop layer (not shown) and a second doped dielectric layer may be successively deposited on the oxygen rich cap layer 120 for subsequent processes, such as a damascene process. In this embodiment, the etch stop layer may comprise at least N, O, or C. For example, the etch stop layer may comprise silicon nitride, silicon oxynitride, or silicon carbonitride. Moreover, the etch stop layer has a thickness less than 1000 Å. Additionally, the second doped dielectric layer comprises an in-situ oxygen rich cap layer thereon. The second doped dielectric layer may comprise a material the same as or different than the underlying doped dielectric layer 110.

While the invention has been described by way of Example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

1. A method for capping over a doped dielectric, comprising:
depositing a doped dielectric layer on a substrate from a gas mixture comprising a silicon source gas, a dopant gas and an oxygen source gas; and
in-situ depositing an cap layer on the doped dielectric layer from the gas mixture substantially in absence of the dopant gas, wherein a radio frequency (RF) power of about 500˜5000 Watts is applied during deposition of the cap layer.

2. (canceled)

3. The method of claim 1, wherein the radio frequency power is applied for less than 10 sec.

4. The method of claim 1, wherein the silicon source gas comprises SiH₄.

5. The method of claim 1, wherein the dopant gas comprises at least SiF₄, B₂H₆ or PH₃.

6. The method of claim 1, wherein the oxygen source gas comprises N₂O.

7. The method of claim 1, wherein the doped dielectric layer and the cap layer are formed by plasma enhanced chemical vapor deposition (PECVD) process.

8. The method of claim 1, wherein the cap layer is an oxygen rich cap layer.

9. The method of claim 8, wherein the oxygen rich cap layer has an oxygen to silicon ratio of about 1.8˜2.5.

10. The method of claim 8, wherein the oxygen rich cap layer has a refractive index of about 1.42˜1.46.

11. The method of claim 8, wherein the oxygen rich cap layer has a thickness less than 500 Å.

12. The method of claim 1, wherein the dopant content near the top surface of the cap layer is lower than that in the doped dielectric layer.

13. The method of claim 1, wherein the cap layer has a gradient dopant concentration therein and the dopant content near the top surface of the cap layer is substantially equal to zero.

14. A method for capping over a doped dielectric, comprising:
providing a substrate in a chamber;
injecting a gas mixture into the chamber, the gas mixture comprises a silicon source gas, a fluorine source gas and an oxygen source gas;
generating a plasma to deposit a fluorine-doped silicon glass layer on the substrate by applying a radio frequency power; and
in-situ depositing an cap layer on the fluorine-doped silicon glass layer by continuing to apply the radio frequency power and injecting the silicon source gas and the oxygen source gas into the chamber, while substantially stopping injection of the fluorine source gas;
wherein the fluorine content is lower than that in the fluorine-doped silicon glass layer.

15. The method of claim 14, wherein the applied radio frequency power is about 500˜5000 Watts.

16. The method of claim 14, wherein the radio frequency power for deposition of the cap layer is applied for less than 10 sec.

17. The method of claim 14, wherein the silicon source gas comprises SiH₄.

18. The method of claim 14, wherein the fluorine source gas comprises SiF₄.

19. The method of claim 14, wherein the oxygen source gas comprises N₂O.

20. The method of claim 14, wherein the fluorine-doped silicon glass layer and the cap layer are formed by plasma enhanced chemical vapor deposition process.

21. The method of claim 14, wherein the cap layer is an oxygen rich cap layer.

22. The method of claim 21, wherein the oxygen rich cap layer has an oxygen to silicon ratio of about 1.8˜2.5.

23. The method of claim 21, wherein the oxygen rich cap layer has a refractive index of about 1.42˜1.46.

24. The method of claim 21, wherein the oxygen rich cap layer has a thickness less than 500 Å.

25. The method of claim 14, wherein the cap layer has a gradient dopant concentration therein and the dopant content near the top surface of the cap layer is substantially equal to zero.
